(19) United States
(12) Patent Application Publication
(10) Pub. No.: US 2025/0379159 A1
(43) Pub. Date: Dec. 11, 2025

(54) ELECTRONIC DEVICE

(71) Applicant: Innolux Corporation, Miaoli County (TW)

(72) Inventors: You-Ruey Shen, Miaoli County (TW); Te-Hsun Lin, Miaoli County (TW); Wen-Hsiang Liao, Miaoli County (TW); Ker-Yih Kao, Miaoli County (TW)

(73) Assignee: Innolux Corporation, Miaoli County (TW)

(21) Appl. No.: 19/212,695

(22) Filed: May 20, 2025

Related U.S. Application Data
(60) Provisional application No. 63/658,453, filed on Jun. 11, 2024.

(30) Foreign Application Priority Data
Dec. 27, 2024 (CN) 202411952800.3

(51) Int. Cl. H01L 23/00; H01L 21/48; H01L 23/31; H01L 23/367; H01L 23/498; H01L 23/538

(52) U.S. Cl. CPC H01L 23/562; H01L 21/4857; H01L 23/3128; H01L 23/3135; H01L 23/3675; H01L 23/49816; H01L 23/5383; H01L 23/5389; H01L 23/564; H01L 24/19; H01L 24/20; H01L 2224/214; H01L 2924/3512

(57) ABSTRACT

An electronic device, including an electronic unit, a package layer, a circuit structure, and a first heat dissipation layer, is provided. The package layer surrounds the electronic unit. The circuit structure is disposed on the package layer and is electrically connected to the electronic unit. The first heat dissipation layer is disposed on the package layer and is opposite to the circuit structure. The circuit structure includes a conductive portion and an insulative portion surrounding the conductive portion. The first heat dissipation layer includes a first volume, the conductive portion includes a second volume, and the first volume is greater than or equal to the second volume.

### CROSS-REFERENCE TO RELATED APPLICATION

This application claims the priority benefit of U.S. Provisional Application No. 63/658,453, filed on Jun. 11, 2024 and China Application No. 202411952800.3, filed on Dec. 27, 2024. The entirety of each of the above-mentioned patent applications is hereby incorporated by reference herein and made a part of this specification.

### BACKGROUND

### Technical Field

The disclosure relates to an electronic device, and more particularly to an electronic device having improved structural reliability.

### Description of Related Art

An electronic device or a semiconductor device may be formed through a panel-level package (PLP) process or a wafer-level package (WLP) process. Since there are differences in thermal expansion coefficients between components in the electronic device or the semiconductor device, when the mismatch in the thermal expansion coefficients is too large, warpage stress generated in the panel-level package process may easily cause an electronic unit to crack. In particular, when a back surface of the electronic unit is damaged, the risk of cracking is greater. Therefore, how to reduce or prevent warping of the electronic device to improve the structural reliability of the electronic device has become one of the issues that need to be solved urgently.

### SUMMARY

The disclosure provides an electronic device having improved structural reliability.

According to an embodiment of the disclosure, an electronic device includes an electronic unit, a package layer, a circuit structure, and a first heat dissipation layer. The package layer surrounds the electronic unit. The circuit structure is disposed on the package layer and is electrically connected to the electronic unit. The first heat dissipation layer is disposed on the package layer and is opposite to the circuit structure. The circuit structure includes a conductive portion and an insulative portion surrounding the conductive portion. The first heat dissipation layer includes a first volume, the conductive portion includes a second volume, and the first volume is greater than or equal to the second volume.

Based on the above, in the embodiments of the disclosure, in the first heat dissipation layer and the circuit structure disposed on two opposite sides of the electronic unit, the first volume of the first heat dissipation layer is greater than or equal to the second volume of the conductive portion of the circuit structure, so as to improve and/or enhance the anti-cracking strength of the electronic unit, so that the electronic device of the disclosure may have improved structural reliability.

In order for the features and advantages of the disclosure to be more comprehensible, the following embodiments are described in detail in conjunction with the drawings.

### BRIEF DESCRIPTION OF THE DRAWINGS

FIG. 1A is a top schematic view of an electronic device according to an embodiment of the disclosure.

FIG. 1B is a cross-sectional schematic view along a line I-I of FIG. 1A.

FIG. 2 is a cross-sectional schematic view of an electronic device according to another embodiment of the disclosure.

FIG. 3 is a cross-sectional schematic view of an electronic device according to another embodiment of the disclosure.

FIG. 4 is a cross-sectional schematic view of an electronic device according to another embodiment of the disclosure.

FIG. 5 is a cross-sectional schematic view of an electronic device according to another embodiment of the disclosure.

FIG. 6 is a cross-sectional schematic view of an electronic device according to another embodiment of the disclosure.

FIG. 7A to FIG. 7C are cross-sectional schematic views of a manufacturing method of an electronic device according to an embodiment of the disclosure.

FIG. 8 is a cross-sectional schematic view of an electronic device according to another embodiment of the disclosure.

FIG. 9 is a cross-sectional schematic view of an electronic device according to another embodiment of the disclosure.

### DESCRIPTION OF THE EMBODIMENTS

The disclosure may be understood through referring to the following detailed description in conjunction with the drawings. It should be noted that in order to facilitate the understanding by the reader and for the conciseness of the drawings, multiple drawings in the disclosure only depict a part of an electronic device, and specific elements in the drawings are not drawn according to actual scale. In addition, the number and the size of each element in the drawings are only for illustration and are not intended to limit the scope of the disclosure.

Throughout the specification and the appended claims of the disclosure, certain words are used to refer to specific elements. Persons skilled in the art should understand that electronic device manufacturers may refer to the same elements by different names. The disclosure does not intend to distinguish the elements with the same function but different names.

In the following specification and claims, words such as “containing” and “comprising” are open-ended words, which should be interpreted as “including but not limited to . . . ”.

In addition, relative terms such as “below” or “bottom portion” and “above” or “top portion” may be used in the embodiments to describe the relative relationship between an element and another element in the drawings. It should be understood that if a device in the drawings is flipped upside down, elements described as “below” will become elements described as “above”.

In some embodiments of the disclosure, terms related to bonding and connection, such as “connection” and “interconnection”, unless otherwise defined, may refer to two structures that are directly in contact or may also refer to two structures that are not directly (indirectly) in contact, wherein there is another structure provided between the two structures. Also, the terms related to bonding and connection may also include the case where two structures are both movable or two structures are both fixed. Furthermore, the term “coupling” includes the transfer of energy between two structures through means of direct or indirect electrical connection or the transfer of energy between two separate structures by means of mutual induction.

It should be understood that when an element or a film layer is referred to as being “on” another element or film layer or “connected to” another element or film layer, the element may be directly on the another element or film layer or directly connected to the another element or film layer, or there may be an element or a film layer inserted between the two (indirect case). In contrast, when an element is referred to as being “directly on” another element or film layer or “directly connected to” another element or film layer, there is no element or film layer inserted between the two.

The terms “about”, “equal to”, “equivalent” or “same”, “substantially”, or “roughly” are generally interpreted as within 20% of a given value or range, or interpreted as within 10%, 5%, 3%, 2%, 1%, or 0.5% of the given value or range.

In the disclosure, the area, the width, the thickness, or the height of each assembly or the distance or the spacing between assemblies may be measured using an optical microscope (OM), a scanning electron microscope (SEM), an α-step, an ellipsometer, or other suitable manners. Specifically, according to some embodiments, by using the scanning electron microscope, a cross-sectional structural image including an assembly to be measured may be obtained, and the area, the width, the thickness, or the height of each assembly or the distance or the spacing between the assemblies is measured.

In the disclosure, the definition of roughness judgment may be observed by the SEM. On an uneven surface, it can be seen that there is a distance difference of 0.15 μm to 1 μm between peaks and valleys of surface undulations. The measurement of roughness judgment may include using the SEM, a transmission electron microscope (TEM), etc. to observe the surface undulations at the same appropriate magnification, and comparing the undulations by taking a sample of unit length (for example, 10 μm), which is a roughness range thereof. Here, “appropriate magnification” means that at least one surface may have a roughness (Rz) or an average roughness (Ra) of at least 10 peaks and valleys visible under the field of view of such a magnification.

As used herein, the terms “film” and/or “layer” may refer to any continuous or discontinuous structure and material (for example, a material deposited by a method of the disclosure). For example, the film and/or the layer may include a two-dimensional material, a three-dimensional material, nanoparticles, or even a partial or complete molecular layer, a partial or complete atomic layer, or atomic and/or molecular clusters. The film or the layer may include a material or a layer having pinholes, which may be at least partially continuous.

Although the terms first, second, third . . . may be used to describe various constituent elements, the constituent elements are not limited by the terms. The terms are only used to distinguish a single constituent element from other constituent elements in the specification. The same terms may not be used in the claims, but replaced by first, second, third . . . according to the order in which the elements are declared in the claims. Therefore, in the following specification, a first constituent element may be a second constituent element in the claims.

Unless otherwise defined, all terms (including technical and scientific terms) used herein have the same meaning as commonly understood by persons skilled in the art to which the disclosure belongs. It should be understood that the terms, such as the terms defined in commonly used dictionaries, should be interpreted as having meanings consistent with the prior art and the background or context of the disclosure, and should not be interpreted in an idealized or overly formal manner, unless specifically defined herein.

It should be noted that in the following embodiments, the technical features of several different embodiments may be replaced, reorganized, and mixed to complete other embodiments without departing from the spirit of the disclosure.

An electronic device of the disclosure may include a power module, a semiconductor device, a semiconductor package device, a display device, an antenna device, a sensing device, a light emitting device, or a splicing device, but not limited thereto. The electronic device may include a bendable or flexible electronic device. The electronic device may include an electronic element. The electronic element may include a passive element, an active element, or a combination of the above, such as a capacitor, a resistor, an inductor, a variable capacitor, a filter, a diode, a transistor, a sensor, a microelectromechanical system (MEMS) element, and a liquid crystal chip, but not limited thereto. The diode may include a light emitting diode or a non-light emitting diode. The diode includes a P-N junction diode, a PIN diode, or a constant current diode. The light emitting diode may include, for example, an organic light emitting diode (OLED), a mini LED, a micro LED, a quantum dot LED, fluorescence, phosphor, other suitable materials, or a combination of the above, but not limited thereto. The sensor may include, for example, a capacitive sensor, an optical sensor, an electromagnetic sensor, a fingerprint sensor (FPS), a touch sensor, an antenna, a pen sensor, etc., but not limited thereto. The following description will take the display device as the electronic device to illustrate the disclosure, but the disclosure is not limited thereto. According to an embodiment of the disclosure, a manufacturing method of the electronic device provided may be applied, for example, to a wafer-level package (WLP) process or a panel-level package (PLP) process and may adopt a chip first process or a chip last/RDL first process, which will be further described in detail below. The electronic device referred to in the disclosure may include a system on chip (SoC), a system in package (SiP), an antenna in package (AiP), co-packaged optics (CPO), or a combination of the above, but not limited thereto.

Reference will now be made in detail to the exemplary embodiments of the disclosure, and examples of the exemplary embodiments are illustrated in the drawings. Wherever possible, the same reference numerals are used in the drawings and the description to refer to the same or similar parts.

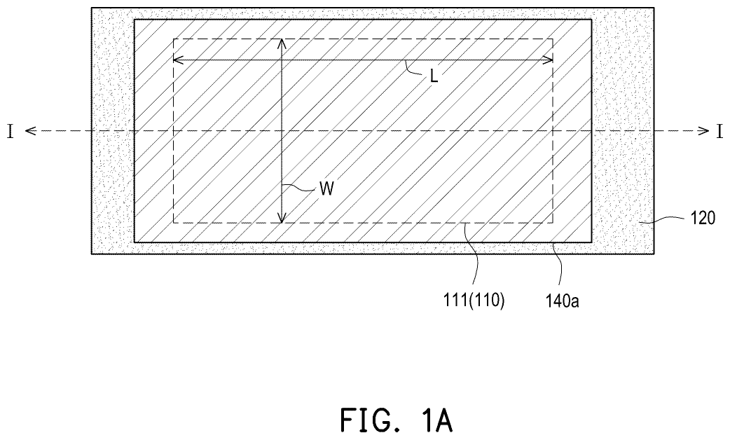

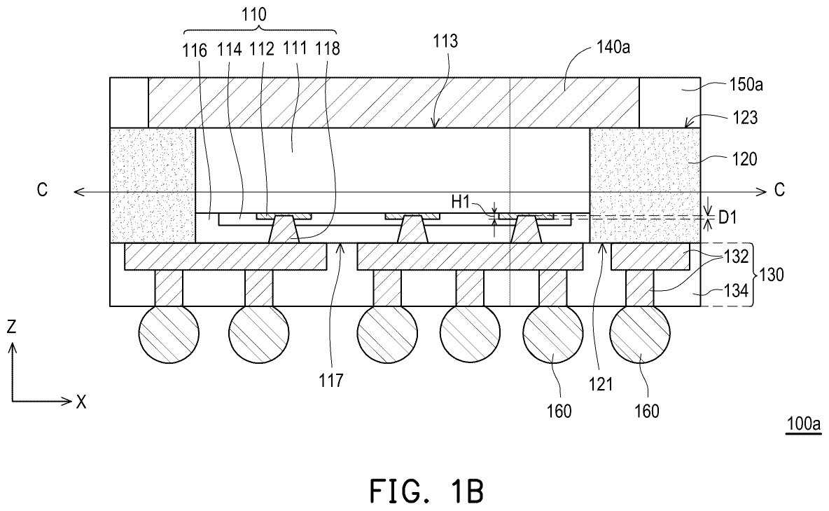

FIG. 1A is a top schematic view of an electronic device according to an embodiment of the disclosure. FIG. 1B is a cross-sectional schematic view along a line I-I of FIG. 1A. For the convenience of explanation, FIG. 1A illustrates the electronic device by omitting some components. Please refer to FIG. 1A and FIG. 1B at the same time. In the embodiment, an electronic device 100a includes an electronic unit 110, a package layer 120, a circuit structure 130, and a first heat dissipation layer 140a. The package layer 120 surrounds the electronic unit 110. The circuit structure 130 is disposed on the package layer 120 and is electrically connected to the electronic unit 110. The first heat dissipation layer 140a is disposed on the package layer 120 and is opposite to the circuit structure 130. The circuit structure 130 includes a conductive portion 132 and an insulative portion 134 surrounding the conductive portion 132. The first heat dissipation layer 140a includes a first volume, the conductive portion 132 includes a second volume, and the first volume is greater than or equal to the second volume.

In the embodiment, the electronic unit 110 may include a chip 111. In a top view, the chip 111 has a length L and a width W, and a ratio (L/W) of the length L to the width W is between 1 and 5. In an embodiment, the chip 111 includes an active assembly and a passive assembly formed therein, but not limited thereto. The electronic unit 110 may further include a pad 112, a passivation layer 114, an insulation layer 116, and a first conductor layer 118. The pad 112 is disposed on the chip 111 and may be electrically connected to other conductive assemblies, wherein the material of the pad 112 may be, for example, aluminum, copper, nickel, molybdenum, titanium, an alloy or a combination of the above materials, or other appropriate metal materials, but not limited thereto. The passivation layer 114 is formed on the chip 111 and has a contact opening exposing apart of the pad 112. The passivation layer 114 may be, for example, a silicon oxide layer, a silicon nitride layer, a silicon oxynitride layer, photosensitive polyimide, photosensitive polyimide (PSPI), polybenzoxazole (PBO), benzocyclobutene (BCB), or a dielectric layer formed by other appropriate dielectric materials, but not limited thereto. The insulation layer 116 is formed on the passivation layer 114, and a contact opening of the insulation layer 116 partially exposes the pad 112. The pad 112 may be, for example, an input/output (I/O) pad of the electronic unit 110. Along a direction X perpendicular to a direction Z, the width of the insulation layer 116 is greater than the width of the passivation layer 114. In other words, the insulation layer 116 may contact a surface of the chip 111. According to some embodiments, the surface of the chip 111 contacting the insulation layer 116 may have a rough surface, that is, the surface roughness of the chip 111 contacting the insulation layer 116 may be greater than the surface roughness of the chip 111 contacting the passivation layer 114, so as to improve the bonding strength, but not limited thereto. According to some embodiments, the water absorption rate of the insulation layer 116 may be less than the water absorption rate of the passivation layer 114, so as to improve the water resistance ability of the electronic device, thereby improving the reliability. According to some embodiments, the light transmittance of the insulation layer 116 is at least greater than or equal to 50%, so as to improve the alignment accuracy when executing a patterning step or improve the detectivity when executing a detection step, but not limited thereto. Light may include visible light or infrared light, but not limited thereto. The insulation layer 116 may be, for example, polyimide, photosensitive polyimide, polybenzoxazole, benzocyclobutene, a build-up film, an epoxy resin layer, or a dielectric layer formed by other appropriate polymers, but not limited thereto. The first conductor layer 118 is formed on the pad 112, wherein the material of the first conductor layer 118 may be, for example, copper, but not limited thereto. In an embodiment, along the direction Z, the pad 112 has a first height H1, and a part of the first conductor layer 118 may be embedded in the pad 112 with an embedded depth D1, wherein a ratio of the embedded depth D1 to the first height H1 may be greater than or equal to 0.05 and less than or equal to 0.5 (0.05≤D1/H1≤0.5), and the depth D1 is, for example, 1 μm to 10 μm, but not limited thereto. Such a design may reduce the contact impedance between the first conductor layer 118 and the pad 112. In an embodiment, the electronic unit 110 may be, for example, a known good die (KGD), a diode, an antenna unit, a transducer, a structure of a semiconductor-related process, or a structure produced by a semiconductor-related process disposed on a substrate (for example, polyimide, glass, silicon, or other suitable substrate materials), but not limited thereto.

Furthermore, the package layer 120 of the embodiment surrounds the electronic unit 110, and the package layer 120 has a first side 121 and a second side 123 opposite to each other. In the embodiment, “an assembly surrounds another assembly” may mean that the assembly may at least partially contact a side surface of the another assembly in the cross-sectional view of the electronic device 100a. As shown in FIG. 1B, the package layer 120 may directly contact a side surface of the electronic unit 110. The package layer 120 may provide a water vapor proof effect to the electronic unit 110, thereby improving the reliability of the electronic device 100a. In an embodiment, the material of the package layer 120 is, for example, an insulating material, which may include a silicon oxide layer, a silicon nitride layer, a silicon oxynitride layer, a polymer, or an epoxy molding compound (EMC), wherein the package layer 120 is formed, for example, by a deposition process or a molding process, but not limited thereto.

Furthermore, the electronic device 100a of the embodiment includes the first heat dissipation layer 140a disposed on a back surface 113 of the electronic unit 110. The back surface 113 of the electronic unit 110 is a side opposite to the pad 112. The first heat dissipation layer 140a is disposed on the second side 123 of the package layer 120, and in addition to directly contacting the back surface 113 of the electronic unit 110, the first heat dissipation layer 140a also extends to contact a part of the package layer 120. In an embodiment, the material of the first heat dissipation layer 140a is, for example, a heat sink including copper, aluminum, an alloy, ceramic, graphene, a ceramic material, a combination thereof, or other suitable materials. The heat dissipation coefficient of the first heat dissipation layer 140a may be greater than or equal to 50 (W/m·K) and less than or equal to 450 (W/m·K).

Furthermore, the circuit structure 130 of the embodiment is disposed on the first side 121 of the package layer 120, and a stacking direction of the insulative portion 134 and the conductive portion 132 of the circuit structure 130 may be along the direction Z and may be stacked into any suitable structure. In an embodiment, the circuit structure 130 may directly contact the first side 121 of the package layer 120 and an active surface 117 of the chip 111, wherein the first conductor layer 118 of the electronic unit 110 may directly contact the conductive portion 132 of the circuit structure 130 and may be electrically connected to the circuit structure 130. In an embodiment, the conductive portion 132 is, for example, a route, a conductive through hole, a conductive blind hole, a pad, or a combination thereof, as long as there is a conductive function, the same belongs to the conductive portion described in the disclosure. In an embodiment, the material of the conductive portion 132 may be, for example, copper, titanium, nickel, or a combination or an alloy of the above materials, but not limited thereto. In an embodiment, the material of the insulative portion 134 may be, for example, a build-up film, polyimide, epoxy, silicon dioxide, silicon nitride, solder resist, or a combination thereof, but not limited thereto. The direction Z described in the disclosure may be the normal direction of the electronic unit.

In an embodiment, the circuit structure 130 may also be referred to as a redistribution structure. The redistribution structure may be electrically connected to a chip or other electronic assemblies through a solder ball or other bonding assemblies. The redistribution structure may include at least one dielectric layer and at least one conductive layer alternately stacked along the direction Z. Through the at least one dielectric layer and the at least one conductive layer, routes may be redistributed and/or the fan-out or fan-in areas thereof may be increased, or different electronic assemblies may be electrically connected to each other through the redistribution structure. For example, a pitch between two adjacent contact pads at one end of the redistribution structure contacting the electronic assembly may be less than or equal to a pitch between two adjacent contact pads at one end of the redistribution structure away from the electronic assembly. Therefore, the redistribution structure may adjust the route fan-out condition or electrically connect the circuit structure/the electronic assembly with a first pitch to the circuit structure/the electronic assembly with a second pitch, but not limited thereto. A method of forming the redistribution structure may include forming the at least one dielectric layer and the at least one conductive layer using a lithography process, a surface treatment process, a laser process, an electroplating process, a deposition process, or other processes. The surface treatment process includes roughening or activating a surface of the dielectric layer or a surface of the conductive layer to improve the bonding ability thereof. For example, the bonding strength between subsequent film layers is improved by increasing the surface roughness.

In addition, the electronic device 100a of the embodiment further includes a buffer layer 150a disposed on the second side 123 of the package layer 120 and surrounding the first heat dissipation layer 140a. In the embodiment, the buffer layer 150a directly contacts the second side 123 of the package layer 120 and the first heat dissipation layer 140a. In an embodiment, the material of the buffer layer 150a is, for example, an organic material or an inorganic material, but not limited thereto.

Please refer to FIG. 1B again. In the embodiment, the first volume of the first heat dissipation layer 140a is greater than or equal to the second volume of the conductive portion 132 of the circuit structure 130. Here, the volumes as mentioned above are both volumes where metal materials are adopted. Specifically, in a top view, a projected area of the conductive portion and a projected area of the first heat dissipation layer may be obtained, and in a cross-sectional view, a thickness of the conductive portion and a thickness of the first heat dissipation layer may be obtained, wherein an integral value of the projected area and the thickness is the volume. According to some embodiments, when the heat dissipation layer or the circuit structure has multiple conductive layers or metal layers stacked on each other, the area of each conductive layer or metal layer may be obtained through an X-ray detector, an infrared detector, or other devices. In an embodiment, a ratio of the first volume to the second volume is greater than or equal to 1 and less than or equal to 2. In an embodiment, the ratio of the first volume to the second volume is greater than or equal to 1.1 and less than or equal to 1.9. In an embodiment, the electronic unit 110, the package layer 120, the circuit structure 130, the first heat dissipation layer 140a, and the buffer layer 150a in the electronic device 100a may be regarded as one package unit, and a center line C of the package unit is taken along the direction X to divide the package unit into an upper half portion and a lower half portion. The upper half portion includes a metal portion (for example, the first heat dissipation layer 140a) and a non-metal portion (for example, a part of the package layer 120, the buffer layer 150a, etc.), and the thermal expansion coefficient of the metal portion and the thermal expansion coefficient of the non-metal portion are calculated to obtain a mixed thermal expansion coefficient of the upper half portion. Similarly, the lower half portion includes a metal portion (for example, the conductive portion 132 of the circuit structure 130, etc.) and a non-metal portion (for example, the package layer 120, a part of the insulative portion 134 of the circuit structure 130, etc.), and the thermal expansion coefficient of the metal portion and the thermal expansion coefficient of the non-metal portion are calculated to obtain a mixed thermal expansion coefficient of the lower half portion. If the center line passes through a structural layer and divides the structural layer into an upper portion and a lower portion, the thermal expansion coefficient may be calculated according to the ratio of division. In an embodiment, when the center line is between the chip 111 and the pad 112 of the electronic unit 110, a ratio of the mixed thermal expansion coefficient of the upper half portion to the mixed thermal expansion coefficient of the lower half portion is between 1.1 and 1.6. In an embodiment, when the center line is between the chip 111 and the pad 112 of the electronic unit 110, the ratio of the mixed thermal expansion coefficient of the upper half portion to the mixed thermal expansion coefficient of the lower half portion is between 1.4 and 1.9. The center line of the disclosure may be an extension line at a position of half of the electronic device in a cross-sectional schematic view. The upper half portion and the lower half portion refer to portions respectively located on two opposite sides of the center line.

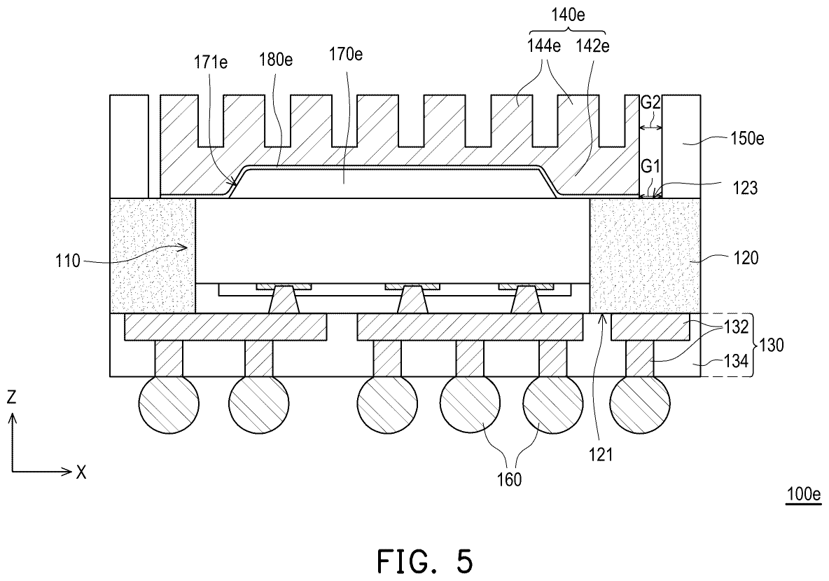

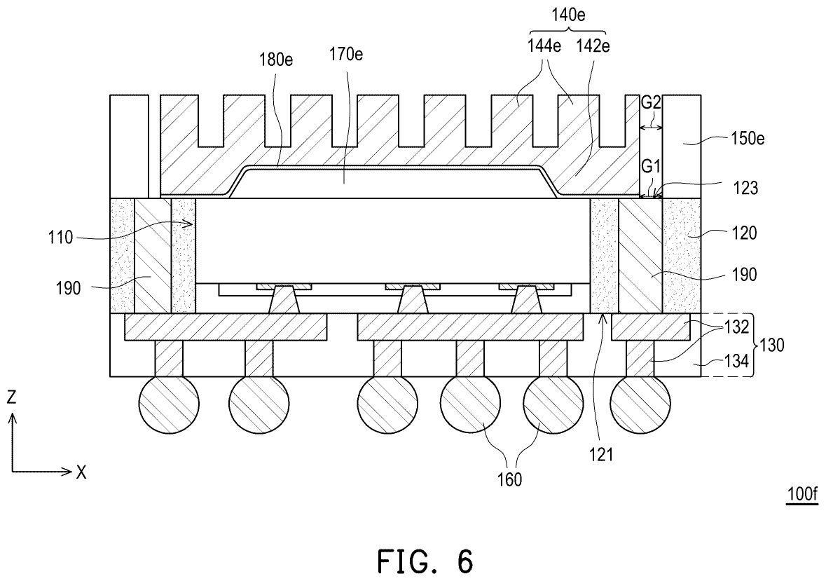

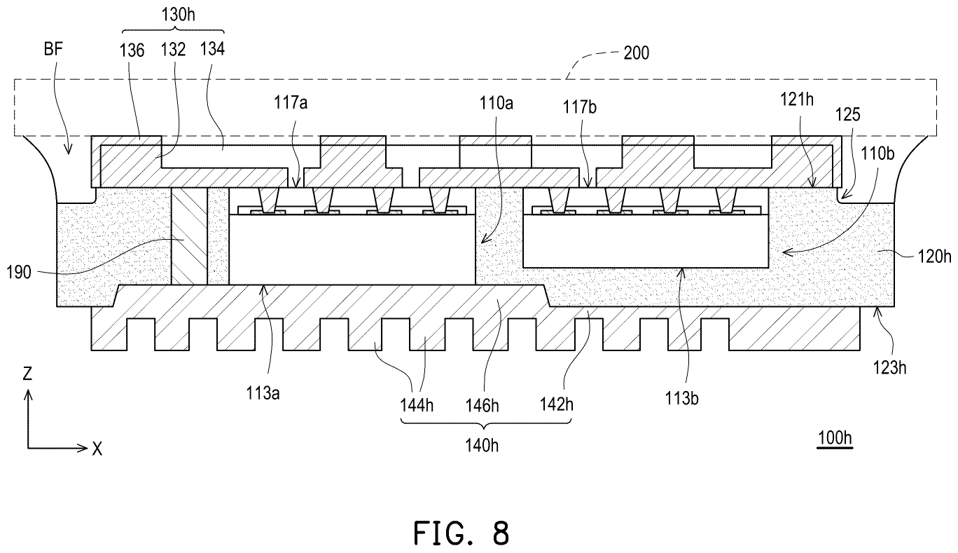

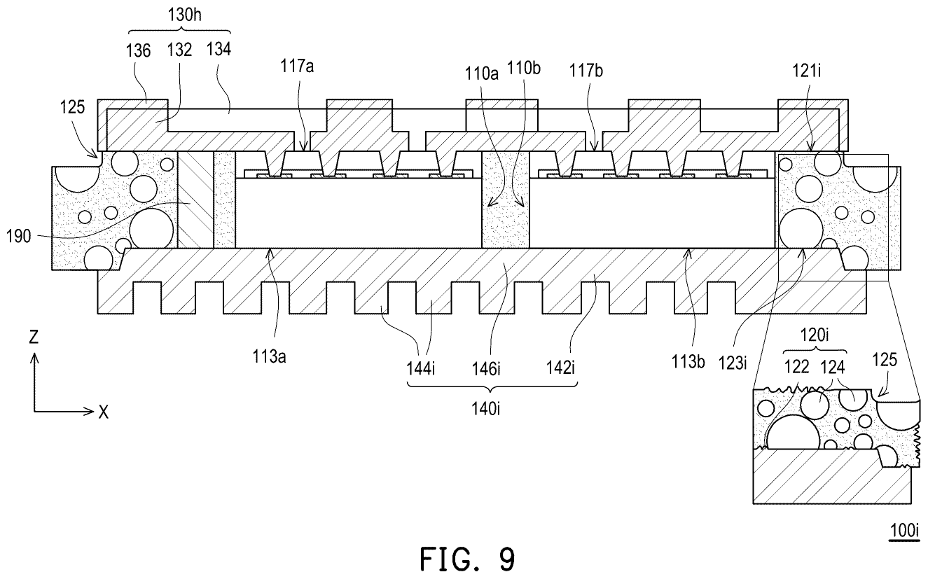

Please refer to FIG. 1A again. The ratio (L/W) of the length L to the width W of the chip 111 of the embodiment is between 1 and 5. In an embodiment, when the ratio (L/W) of the length L to the width W of the chip 111 is 1.5, the ratio of the mixed thermal expansion coefficient of the upper half portion to the mixed thermal expansion coefficient of the lower half portion is between 1.3 and 1.8. In an embodiment, when the ratio (L/W) of the length L to the width W of the chip 111 is 2.3, the ratio of the mixed thermal expansion coefficient of the upper half portion to the mixed thermal expansion coefficient of the lower half portion is between 1.2 and 1.7. In an embodiment, when the ratio (L/W) of the length L to the width W of the chip 111 is 2.8, the ratio of the mixed thermal expansion coefficient of the upper half portion to the mixed thermal expansion coefficient of the lower half portion is between 1.1 and 1.65. In an embodiment, when the ratio (L/W) of the length L to the width W of the chip 111 is 4.6, the ratio of the mixed thermal expansion coefficient of the upper half portion to the mixed thermal expansion coefficient of the lower half portion is between 1.0 and 1.6. In short, when the circuit structure 130 is formed on one side of the electronic unit 110, a heat dissipation layer 140 may be formed on the other side of the electronic unit 110, that is, the side opposite to the circuit structure 130. By calculating the volume of the conductive portion of the circuit structure 130 and the volume of a heat dissipation portion (for example, a metal or heat dissipation assembly) of the heat dissipation layer 140, whether the ratio of the mixed thermal expansion coefficient of the upper half portion to the mixed thermal expansion coefficient of the lower half portion belongs to a safe design may be obtained, thereby reducing the risk of cracking of the electronic device. In a simulation embodiment, when the ratio (L/W) of the length L to the width W of the chip 111 is 1.24, the strength of the chip 111 is 353.4 MPa. In a simulation embodiment, when the ratio (L/W) of the length L to the width W of the chip 111 is 2.88, the strength of the chip 111 is 155.8 MPa. In a simulation embodiment, in the same chip, the stress at the corner of the chip is greater than the stress at the edge of the chip, and the stress at the edge of the chip is greater than the internal stress of the chip. Therefore, the thickness at the corner of the heat dissipation layer 140 may be adjusted to be different from the thicknesses at other positions. For example, the thickness at the corner of the heat dissipation layer 140 is different from the thickness at where the heat dissipation layer 140 overlaps with the chip 111, see FIG. 5, FIG. 6, FIG. 8, and FIG. 9. Through understanding the aspect ratio of the chip of the electronic device, the appropriate ratio of the mixed thermal expansion coefficient of the upper half portion to the mixed thermal expansion coefficient of the lower half portion is selected, thereby obtaining the appropriate design of the volume of the conductive portion and the volume of the heat dissipation layer, which may reduce the risk of cracking of the electronic device, but not limited thereto.

In addition, the electronic device 100a of the embodiment further includes a connector 160 disposed on the circuit structure 130 and electrically connected to the circuit structure 130. The electronic device 100a may be electrically connected to an external circuit through the connector 160. In an embodiment, the connector 160 may be made of, for example, tin, nickel, gold, silver, palladium, copper, gallium, an alloy thereof, or a combination thereof, but not limited thereto. In an embodiment, the connector 160 is, for example, a solder ball, but not limited thereto.

In short, in the embodiment of the disclosure, in the first heat dissipation layer 140a and the circuit structure 130 disposed on two opposite sides of the electronic unit 110, the first volume of the first heat dissipation layer 140a is greater than or equal to the second volume of the conductive portion 132 of the circuit structure 130, so as to improve and/or enhance the anti-cracking strength of the electronic unit 110, so that the electronic device 100a of the disclosure may have improved structural reliability.

It should be noted that the following embodiments continue to use the reference numerals and some content of the foregoing embodiment, wherein the same reference numerals are adopted to represent the same or similar elements, and the description of the same technical content is omitted. Reference may be made to the foregoing embodiment for the description of the omitted part, which will not be repeated in the following embodiments.

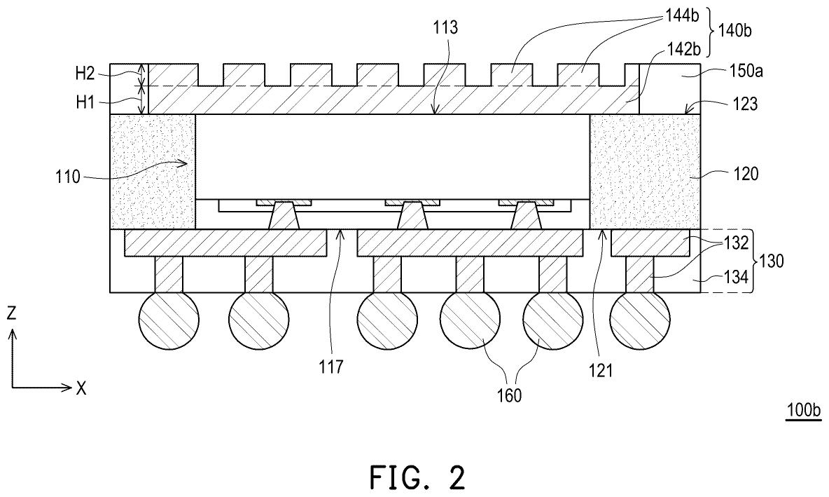

FIG. 2 is a cross-sectional schematic view of an electronic device according to another embodiment of the disclosure. Please refer to FIG. 1B and FIG. 2 at the same time. An electronic device 100b of the embodiment is similar to the electronic device 100a of FIG. 1B, and the difference between the two is that in the embodiment, a first heat dissipation layer 140b may include a first portion 142b and a plurality of second portions 144b, wherein the first portion 142b is located between the electronic unit 110 and the second portions 144b, and the second portions 144b are connected to the first portion 142b. In an embodiment, the first portion 142b may, for example, extend along the direction X, and the second portions 144b are separated from each other and may, for example, extend along the direction Z. In an embodiment, the first portion 142b may be, for example, a heat dissipation base, and the second portion 144b may be, for example, a heat dissipation fin, which may increase the heat dissipation area to enhance heat dissipation. In some embodiments, along the direction Z, the first portion 142b of the heat dissipation layer 140b has a first height H1, the second portion 144b of the first heat dissipation layer 140b has a second height H2, and the first height H1 is greater than the second height H2, but not limited thereto. In an embodiment, in a cross-sectional view, the shape of the second portion 144b may be, for example, a rectangle, a square, a trapezoid, a triangle, a semicircle, an ellipse, an arc, or a combination of the above shapes, which may increase the heat dissipation surface area. In an embodiment, the material of the first conductive layer 140b may be, for example, copper or aluminum, but not limited thereto.

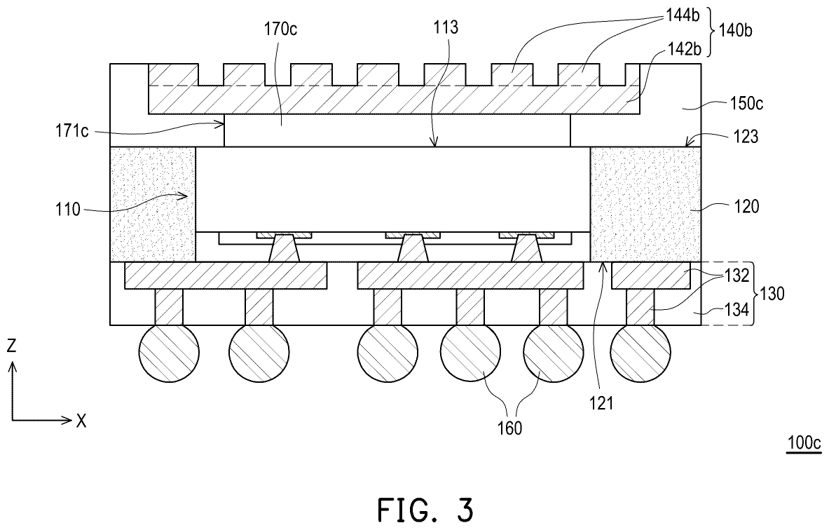

FIG. 3 is a cross-sectional schematic view of an electronic device according to another embodiment of the disclosure. Please refer to FIG. 2 and FIG. 3 at the same time. An electronic device 100c of the embodiment is similar to the electronic device 100b of FIG. 2, and the difference between the two is that in the embodiment, the electronic device 100c further includes a protective layer 170c disposed between the first heat dissipation layer 140b and the electronic unit 110. In an embodiment, the electronic unit 110 may generate a microstructure (for example, a crack) on the back surface 113 during a grinding process, and the protective layer 170c may be directly disposed on the back surface 113 of the electronic unit 110 to fill the microstructure, wherein the protective layer 170c may effectively infiltrate the microstructure to achieve a repairing function, so as to slow down and/or prevent the electronic unit 110 from cracking, which may improve the structural reliability. In an embodiment, the protective layer 170c may partially cover the back surface 113 of the electronic unit 110, that is, the size of the protective layer 170c is smaller than the back surface 113 of the electronic unit 110, and the buffer layer 150c may extend from a side wall to a bottom portion of the first heat dissipation layer 140b to cover a surrounding surface 171c of the protective layer 170c. In an embodiment, the material of the protective layer 170c may be, for example, an organic material or an inorganic material. In an embodiment, the material of the protective layer 170c may be, for example, a composite material or a polymer, wherein the composite material may be, for example, diamond-like carbon, graphene, a cuprocene composite material, or heat conductive silicone; and the polymer may be, for example, polyimide (PI), resin, polyethylene terephthalate (PET), polycarbonate (PC), photoresist (PR), or an Ajinomoto build-up film (ABF), but not limited thereto.

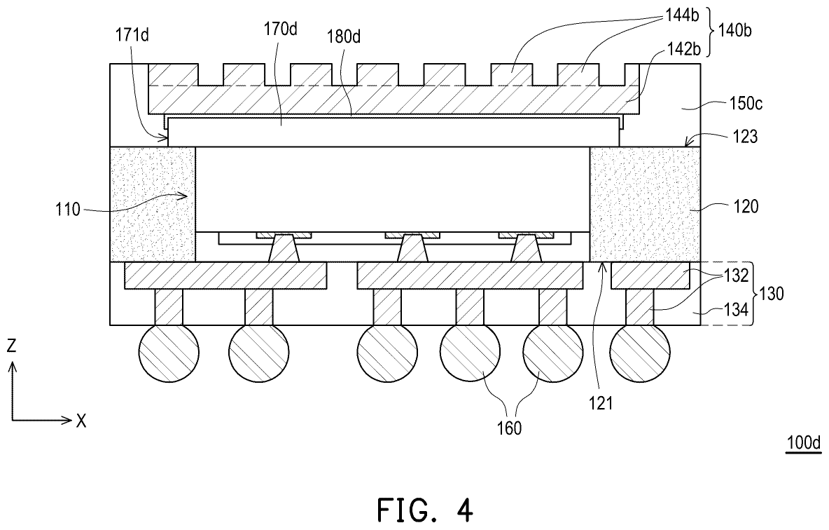

FIG. 4 is a cross-sectional schematic view of an electronic device according to another embodiment of the disclosure. Please refer to FIG. 3 and FIG. 4 at the same time. An electronic device 100d of the embodiment is similar to the electronic device 100c of FIG. 3, and the difference between the two is that in the embodiment, the electronic device 100d further includes a heat conduction layer 180d disposed between a protective layer 170d and the first heat dissipation layer 140b. In an embodiment, the heat conduction layer 180d is conformally disposed with the protective layer 170d. In an embodiment, the heat conduction layer 180d exposes a surrounding surface 171d of the protective layer 170d. In an embodiment, the heat conduction layer 180d is, for example, a thermal interface material (TIM), and the first heat dissipation layer 140b is, for example, an external heat conduction assembly adhered and fixed onto the protective layer 170d through the heat conduction layer 180d. In an embodiment, the heat conduction layer 180d is, for example, a seed layer, and the first heat dissipation layer 140b is formed on the heat conduction layer 180d through such as electroplating process and photolithography process. In an embodiment, the heat conductivity of the first heat dissipation layer 140b may be less than the heat conductivity of the heat conduction layer 180d.

FIG. 5 is a cross-sectional schematic view of an electronic device according to another embodiment of the disclosure. Please refer to FIG. 4 and FIG. 5 at the same time. An electronic device 100e of the embodiment is similar to the electronic device 100d of FIG. 4, and the difference between the two is that in the embodiment, in a cross-sectional view, the shape of a protective layer 170e is trapezoidal, and a heat conduction layer 180e conformally completely covers a surrounding surface 171e of the protective layer 170e and extends onto the second side 123 of the package layer 120. A first portion 142e of a first heat dissipation layer 140e and a second portion 144e thereon are located on the protective layer 170e, and a part of the first portion 142e is also thickened and extends to the edge of the heat conduction layer 180e. In an embodiment, the edge of the first heat dissipation layer 140e may be aligned with the edge of the heat conduction layer 180e. In an embodiment, along the direction X, there is a spacing G1 between a buffer layer 150e and the heat conduction layer 180e, and there is a spacing G2 between the buffer layer 150e and the first heat dissipation layer 140e. In an embodiment, the spacing G1 is less than or equal to the spacing G2. In other words, the buffer layer 150e surrounds the first heat dissipation layer 140e and the heat conduction layer 180e, and does not contact the protective layer 170e, the heat conduction layer 180e, and the first heat dissipation layer 140e.

FIG. 6 is a cross-sectional schematic view of an electronic device according to another embodiment of the disclosure. Please refer to FIG. 5 and FIG. 6 at the same time. An electronic device 100f of the embodiment is similar to the electronic device 100e of FIG. 5, and the difference between the two is that in the embodiment, the electronic device 100f further includes a heat conduction assembly 190 penetrating the package layer 120 and connecting a part of the heat conduction layer 180e and the conductive portion 132 of the circuit structure 130. In an embodiment, the heat conduction assembly 190 may have the function of electrical conduction, heat conduction, or both of electrical conduction and heat conduction.

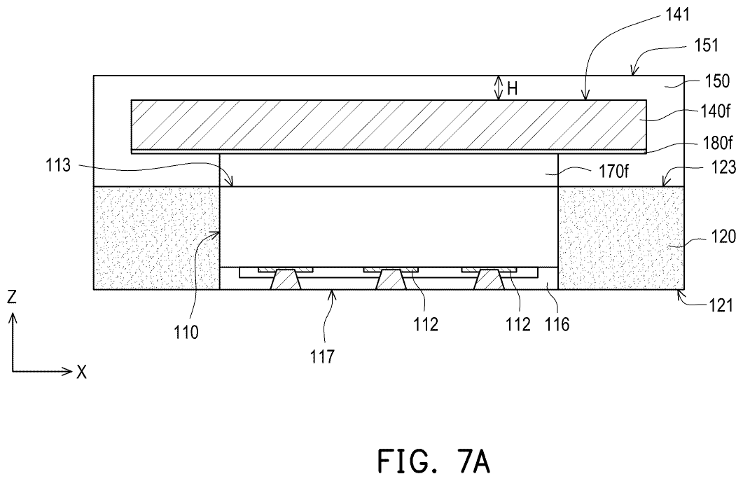

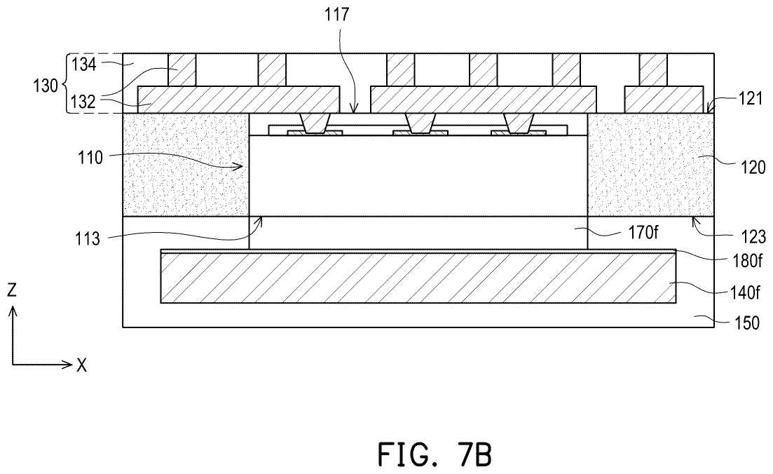

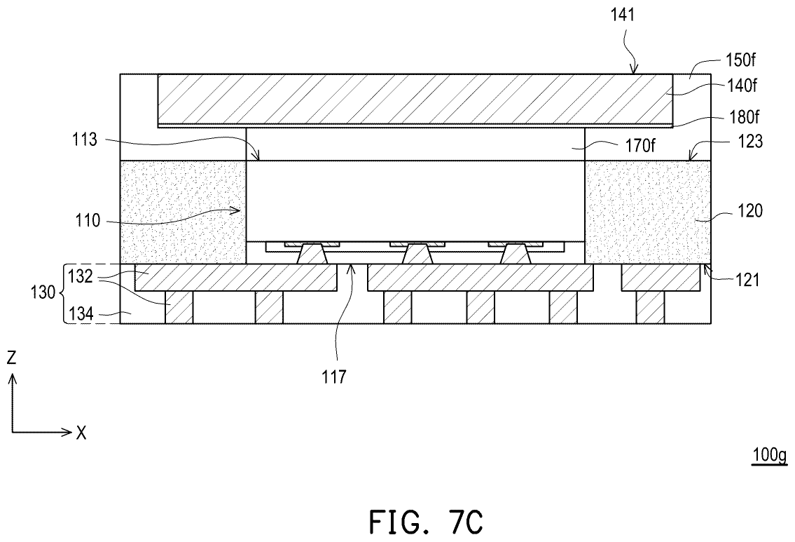

FIG. 7A to FIG. 7C are cross-sectional schematic views of a manufacturing method of an electronic device according to an embodiment of the disclosure. Please refer to FIG. 7A first. Regarding the manufacturing method of the electronic device of the embodiment, first, the electronic unit 110 is disposed on a temporary carrier (not shown) through a temporary adhesive layer (not shown). Next, the package layer 120 is formed on the electronic unit 110, wherein the package layer 120 surrounds the electronic unit 110 to form a package structure. Next, another temporary carrier (not shown) is provided, and the temporary adhesive layer and the temporary carrier are removed. The package structure may be temporarily fixed onto the another temporary carrier so that the back surface 113 of the electronic unit 110 is away from the temporary carrier. In the method described above, if the electronic unit 110 is packaged on the temporary substrate in a manner that the active surface 117 is initially away from the temporary carrier, which may be referred to as a face up process. According to some embodiments, the electronic unit 110 may also be packaged on the temporary carrier in a manner that the active surface 117 faces the temporary carrier, and the back surface 113 of the electronic unit 110 is then exposed, which may be referred to as a face down process.

In an embodiment, the temporary carrier may be, for example, a glass substrate, a printed circuit board, a fiberglass (FR4) substrate, a steel substrate, or other suitable substrates, which are not limited herein. In an embodiment, the package layer 120 may be, for example, a molding compound, epoxy resin, other suitable package materials, or a combination thereof, which is not limited herein. According to some embodiments, a dissociation manner of the adhesive layer may include photo-dissociation, thermal-dissociation, other suitable manners, or a combination of any two thereof. For example, depending on the dissociation manner, the adhesive layer may be used with different types of temporary carriers. For example, the photo-dissociation type adhesive layer may be used with a transparent glass substrate, and the thermal-dissociation type adhesive layer may be used with a steel plate. The adhesive layer may include, for example, an ultraviolet (UV) release tape, a heat release tape (HRT), other suitable materials, or a combination of any two thereof. By disposing the adhesive layer on the temporary carrier, the package structure may be effectively separated.

According to some embodiments, when the face down process is adopted, after the package structure is formed via the molding process, and the package structure is turned upside down, an opening of the insulation layer 116 of the electronic unit 110 may expose the pad 112. When the face up process is adopted, and the package layer 120 overlaps with the pad 112 or the package layer 120 and the insulation layer 116 overlap with the pad 112 at the same time, a patterning process is required to expose the pad 112 to facilitate a subsequent procedure, wherein the patterning process may include photolithography, etching, development, laser, plasma cleaning, a combination thereof, or other suitable steps, which are not limited herein.

Next, please refer to FIG. 7A again. The package layer 120 is ground until the back surface 113 of the electronic unit 110 is exposed, and the package layer 120 having the first side 121 and the second side 123 opposite to each other is formed.

Next, please refer to FIG. 7A again. A protective layer 170f is formed on the second side 123 of the package layer 120. In an embodiment, the protective layer 170f has a flat surface relatively away from the second side 123 of the package layer 120. In an embodiment, the protective layer 170f may have a microstructure, but not limited thereto. In an embodiment, a forming method of the protective layer 170f includes taping, injection molding, slit coating, spin coating, spinless coating, electroplating, chemical plating, deposition (CVD, PVD, ALD, MOCVD, or MPCVD), lamination, or dipping or using a laser beam, microwave, or plasma, but not limited thereto. In an embodiment, the material of the protective layer 170f may be, for example, an organic material or an inorganic material. In an embodiment, the material of the protective layer 170f may be, for example, a composite material or a polymer, wherein the composite material may be, for example, diamond-like carbon, graphene, a cuprocene composite material, or heat conductive silicone; and the polymer may be, for example, polyimide (PI), resin, polyethylene terephthalate (PET), polycarbonate (PC), photoresist (PR), or an Ajinomoto build-up film (ABF), but not limited thereto.

Next, please refer to FIG. 7A again. A heat conduction layer 180f is formed on the protective layer 170f. In an embodiment, the size of the heat conduction layer 180f may be greater than or equal to the size of the protective layer 170f. Next, a first heat dissipation layer 140f is formed on the heat conduction layer 180f, wherein the heat conductivity of the first heat dissipation layer 140f may be different from the heat conductivity of the heat conduction layer 180f. In an embodiment, the heat conduction layer 180f may be, for example, a seed material layer that is a metal layer, which may be a single layer or a composite layer of multiple sub-layers composed of different materials. In an embodiment, the seed material layer may include a titanium layer and a copper layer above the titanium layer, and the seed material layer may be formed using, for example, PVD or a similar method. Next, a patterned photoresist layer is formed on the seed material layer, wherein the patterned photoresist layer exposes a part of the seed material layer. Next, the patterned photoresist layer is used as an electroplating mask to electroplate a metal material onto the seed material layer exposed by the patterned photoresist layer. Next, the patterned photoresist layer and the seed material layer thereunder are removed to form the first heat dissipation layer 140f and the heat conduction layer 180f thereunder. It should be noted that the first heat dissipation layer 140f is provided through electroplating, but not limited thereto. In other embodiments, the heat conduction layer 180f may also be, for example, a thermal interface material (TIM), and the first heat dissipation layer 140f is fixed onto the protective layer 170f through the heat conduction layer 180f. In other words, the first heat dissipation layer 140f is an external heat conduction assembly.

Next, a buffer layer 150 is formed on the second side 123 of the package layer 120, wherein the buffer layer 150 covers the protective layer 170f, the first heat dissipation layer 140f, and the heat conduction layer 180f. At this time, there is a height difference H between a top surface 151 of the buffer layer 150 and a top surface 141 of the first heat dissipation layer 140f, wherein the top surface 151 of the buffer layer 150 is higher than the top surface 141 of the first heat dissipation layer 140f. In an embodiment, the material of the buffer layer 150 is, for example, an organic material or an inorganic material, but not limited thereto.

Next, please refer to FIG. 7A and FIG. 7B at the same time. The structure of FIG. 7A is turned upside down, so that the first side 121 of the package layer 120 faces upward. Next, the circuit structure 130 is formed on the first side 121 of the package layer 120, wherein the circuit structure 130 is electrically connected to the electronic unit 110.

Afterwards, please refer to FIG. 7B and FIG. 7C at the same time. The structure of FIG. 7B is turned upside down, so that the second side 123 of the package layer 120 faces upward. Next, the buffer layer 150 is thinned to form a buffer layer 150f exposing the top surface 141 of the first heat dissipation layer 140f. Finally, the first heat dissipation layer 140f may be patterned to be a fin state according to usage requirements, and a connector may be selectively formed on the circuit structure 130 to be electrically connected an external circuit, so as to complete the manufacture of the semiconductor device.

FIG. 8 is a cross-sectional schematic view of an electronic device according to another embodiment of the disclosure. Please refer to FIG. 1B and FIG. 8 at the same time. An electronic device 100h of the embodiment is similar to the electronic device 100a of FIG. 1B, and the difference between the two is that in the embodiment, the electronic device 100h includes an electronic unit 110a and an electronic unit 110b, wherein the electronic unit 110a and the electronic unit 110b are disposed adjacent to each other, and a package layer 120h surrounds the electronic unit 110a and the electronic unit 110b. An active surface 117a of the electronic unit 110a contacts a circuit structure 130h and is electrically connected to the circuit structure 130h. A back surface 113a of the electronic unit 110a contacts a first heat dissipation layer 140h. An active surface 117b of the electronic unit 110b contacts the circuit structure 130h and is electrically connected to the circuit structure 130h. A back surface 113b of the electronic unit 110b is covered by the package layer 120h. The package layer 120h has a first side 121h and a second side 123h, and the package layer 120h has a curved surface 125 at the edge of the first side 121h. An external assembly 200 is electrically connected to the circuit structure 130h. A buffer layer BF is disposed between the external assembly 200 and the package layer 120h and the circuit structure 130h, a part of the buffer layer BF is disposed in the curved surface 125, and through the design of the curved surface 125, the bonding strength of the electronic device may be increased.

Furthermore, the circuit structure 130h is disposed on the first side 121h of the package layer 120h and includes the conductive portion 132, the insulative portion 134 surrounding the conductive portion 132, and a connecting portion 136 covering an outer side of the insulative portion 134. In an embodiment, the connecting portion 136 may be, for example, a surface treatment layer, which may prevent/slow down oxidation of the conductive portion 132 to protect the conductive portion 132 and may be electrically connected to an external circuit. In an embodiment, the material of the connecting portion 136 is, for example, a nickel layer, a gold layer, a silver layer, or a nickel-palladium-gold layer, but not limited thereto.

In addition, the first heat dissipation layer 140h of the embodiment includes a first portion 142h, a plurality of second portions 144h, and a third portion 146h. The first portion 142h is located between the second portions 144h and the third portion 146h. The second portions 144h are connected to the first portion 142h, and the third portion 146h contacts the back surface 113a of the electronic unit 110a. Here, the third portion 146h of the first heat dissipation layer 140h is embedded in the second side 123h of the package layer 120h and is only partially formed on the first portion 142h, and the first portion 142h of the first heat dissipation layer 140h directly contacts the second side 123h of the package layer 120h. There is no third portion 146h between the back surface 113b of the electronic unit 110b and the first portion 142h. That is, the package layer 120h is filled between the back surface 113b of the electronic unit 110b and the first portion 142h. The first heat dissipation layer 140h includes the first volume, the conductive portion 132 includes the second volume, and the first volume is greater than or equal to the second volume, so as to improve and/or enhance the anti-cracking strengths of the electronic unit 110a and the electronic unit 110b, so that the electronic device 100h of the disclosure may have improved structural reliability.

In addition, in the embodiment, the electronic device 100h further includes the heat conduction assembly 190 penetrating the package layer 120h and connecting the third portion 146h of the first heat dissipation layer 140h and the conductive portion 132 of the circuit structure 130h. In an embodiment, the heat conduction assembly 190 may have the function of electrical conduction, heat conduction, or both of electrical conduction and heat conduction.

FIG. 9 is a cross-sectional schematic view of an electronic device according to another embodiment of the disclosure. Please refer to FIG. 8 and FIG. 9 at the same time. An electronic device 100i of the embodiment is similar to the electronic device 100h of FIG. 8, and the difference between the two is that in the embodiment, a package layer 120i has a first side 121i and a second side 123i, and the package layer 120i has a curved surface 125 at the edge of the first side 121i. Furthermore, the package layer 120i has a microstructure 122 and a filler 124 therein. In an embodiment, the microstructure 122 is located on a surface (for example, an exterior surface) of the package layer 120i, so that the package layer 120i has a rough surface, so as to increase the bonding strength between the package layer 120i and the circuit structure 130h and/or a first heat dissipation layer 140i. The filler 124 may be used to increase the structural stability and/or the supporting strength of the package layer 120i, but not limited thereto. The filler 124 may have various shapes, including, for example, a spherical shape, a rod shape, an irregular shape, or any combination thereof. In an embodiment, the material of the filler 124 may include, but is not limited to, glass fiber, plastic, silanol, mica, oxide, other similar fillers, other insulating materials, or any combination thereof. The particle size of the filler 124 may be between 0.01 μm and 25 μm.

In addition, the first heat dissipation layer 140i of the embodiment includes a first portion 142i, a plurality of second portions 144i, and a third portion 146i. The first portion 142i is located between the second portions 144i and the third portion 146i, and the second portions 144i are connected to the first portion 142i. The third portion 146i of the first heat dissipation layer 140i directly contacts the back surface 113a of the electronic unit 110a and the back surface 113b of the electronic unit 110b, which may increase heat dissipation. Here, the third portion 146i of the first heat dissipation layer 140i is embedded in the second side 123i of the package layer 120i, and the first portion 142i of the first heat dissipation layer 140i directly contacts the second side 123i of the package layer 120i. The first heat dissipation layer 140i includes the first volume, the conductive portion 132 includes the second volume, and the first volume is greater than or equal to the second volume, so as to improve and/or enhance the anti-cracking strengths of the electronic unit 110a and the electronic unit 110b, so that the electronic device 100i of the disclosure may have improved structural reliability.

Furthermore, the first conductor layer 118 and a conductive portion of the circuit structure 130h may be manufactured at the same time or manufactured separately. In other words, the first conductor layer 118 and the conductive portion of the circuit structure 130h may be formed through the same seed layer with an electroplating step. Alternatively, when there is another seed layer between the first conductor layer 118 and the conductive portion of the circuit structure 130h, the first conductor layer 118 and the conductive portion of the circuit structure 130h are manufactured separately.

In summary, in the embodiments of the disclosure, in the first heat dissipation layer and the circuit structure disposed on two opposite sides of the electronic unit, the first volume of the first heat dissipation layer is greater than or equal to the second volume of the conductive portion of the circuit structure, so as to improve and/or enhance the anti-cracking strength of the electronic unit, so that the electronic device of the disclosure may have improved structural reliability.

Finally, it should be noted that the above embodiments are only used to illustrate, but not to limit, the technical solutions of the disclosure. Although the disclosure has been described in detail with reference to the above embodiments, persons skilled in the art should understand that the technical solutions described in the above embodiments may still be modified or some or all of the technical features thereof may be equivalently replaced. However, the modifications or replacements do not cause the essence of the corresponding technical solutions to deviate from the scope of the technical solutions of the embodiments of the disclosure.

What is claimed is:

1. An electronic device, comprising:
an electronic unit;
a package layer, surrounding the electronic unit;
a circuit structure, disposed on the package layer and electrically connected to the electronic unit; and
a first heat dissipation layer, disposed on the package layer and opposite to the circuit structure, wherein the circuit structure comprises a conductive portion and an insulative portion surrounding the conductive portion, the first heat dissipation layer comprises a first volume, the conductive portion comprises a second volume, and the first volume is greater than or equal to the second volume.

2. The electronic device according to claim 1, wherein a ratio of the first volume to the second volume is greater than or equal to 1 and less than or equal to 2.

3. The electronic device according to claim 1, wherein a ratio of the first volume to the second volume is greater than or equal to 1.1 and less than or equal to 1.9.

4. The electronic device according to claim 1, wherein the electronic unit comprises a chip, in a top view, the chip has a length and a width, and a ratio of the length to the width is between 1 and 5.

5. The electronic device according to claim 4, wherein the electronic unit further comprises a pad, a passivation layer, an insulation layer, and a first conductor layer disposed on the chip, the pad has a first height, and a part of the first conductor layer is embedded in the pad, wherein a ratio of an embedded depth to the first height is greater than or equal to 0.05 and less than or equal to 0.5.

6. The electronic device according to claim 1, wherein the first heat dissipation layer comprises a heat sink.

7. The electronic device according to claim 1, wherein a heat dissipation coefficient of the first heat dissipation layer is greater than or equal to 50 (W/m·K) and less than or equal to 450 (W/m·K).

8. The electronic device according to claim 1, further comprising:
a protective layer, disposed between the first heat dissipation layer and the electronic unit.

9. The electronic device according to claim 8, further comprising:
a heat conduction layer, disposed between the protective layer and the first heat dissipation layer.

10. The electronic device according to claim 9, wherein a heat conductivity of the first heat dissipation layer is less than a heat conductivity of the heat conduction layer.

11. The electronic device according to claim 9, wherein an edge of the first heat dissipation layer is aligned with an edge of the heat conduction layer.

12. The electronic device according to claim 9, further comprising:
a heat conduction assembly, penetrating the package layer and connecting a part of the heat conduction layer and the conductive portion of the circuit structure.

13. The electronic device according to claim 12, wherein the heat conduction assembly has a function of electrical conduction, heat conduction, or both of electrical conduction and heat conduction.

14. The electronic device according to claim 1, further comprising:
a buffer layer, disposed on the package layer and surrounding the first heat dissipation layer.

15. The electronic device according to claim 14, wherein there is a spacing between the buffer layer and the first heat dissipation layer.

16. The electronic device according to claim 1, further comprising:
a connector, disposed on the circuit structure and electrically connected to the circuit structure.

17. The electronic device according to claim 1, wherein the first heat dissipation layer comprises a first portion and a plurality of second portions, wherein the first portion is located between the electronic unit and the second portions, and the second portions are connected to the first portion.

18. The electronic device according to claim 17, wherein the first portion of the first heat dissipation layer has a first height, the second portion of the first heat dissipation layer has a second height, and the first height is greater than the second height.

19. The electronic device according to claim 1, wherein the first heat dissipation layer comprises a first portion, a plurality of second portions, and a third portion, the first portion is located between the second portions and the third portion, the second portions are connected to the first portion, and the third portion contacts a back surface of the electronic unit.

20. The electronic device according to claim 19, wherein the third portion of the first heat dissipation layer is embedded in the package layer and is only partially formed on the first portion, and the first portion of the first heat dissipation layer directly contacts the package layer.
